(19) United States
(12) Patent Application Publication
(10) Pub. No.: US 2008/0008019 A1
(43) Pub. Date: Jan. 10, 2008

(54) High Speed Read-Only Memory

(75) Inventor: Suresh BALASURAMANIAN, Coimbatore (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/309,174

(22) Filed: Jul. 6, 2006

(51) Int. Cl. G11C 7/02; G11C 17/00

(52) U.S. Cl. 365/208; 365/94

(57) ABSTRACT

A high speed read-only memory (ROM). Data stored in a memory cell in the ROM array is provided to a sense amplifier in a differential form. Two transistors storing complementary logic states form a memory cell and store a data bit. One transistor has a source terminal connected to a ground terminal while the other transistor has a source terminal left unconnected. The drain terminals of each of the two transistors is connected to a corresponding one of a differential bit-line pair which provides a differential signal representing the stored data bit to a sense amplifier.

### BACKGROUND

1. Field of the Invention

The present invention relates generally to design of memories, and more specifically to a high speed read-only memory (ROM).

2. Related Art

A read-only memory (ROM) generally refers to a memory unit that requires a memory location (cell) to be in an erased condition (typically all bits at logic 1) before it can be written to. In some situations, the memory location cannot be erased at all once written to, and the memory unit in such a situation is termed as a mask ROM.

A mask ROM (unit) generally contains an array of multiple memory cells (mask ROM/memory array) usually organized in rows and columns, with each cell storing a data bit (typically of binary value). In one prior embodiment, a single bit-line is provided corresponding to each column in a mask ROM array, and an accessed memory cell contained in that column provides the stored data bit on the bit-line.

Access circuits are often implemented to retrieve the data bits stored in a mask ROM array. In a prior mask ROM unit, an access circuit contains a sense amplifier, which senses the output of a memory cell (hereafter referred to as cell) provided on a corresponding bit-line (single bit-line sensing) as either a 0 or 1 (assuming only a binary bit is stored). The output of the sense amplifier is often latched according to a latch enable signal, and the latched value thus represents the bit accessed from the mask ROM array.

One problem with such a prior mask ROM device is that the speed of operation (which can be measured as the time taken for the mask ROM device to provide an output after being accessed—also referred to as access time) is relatively slow due to the use of a single bit-line to provide the output of memory cells. This is due, at least in part, to the reason that such a mask ROM device may use small-sized transistors to implement memory cells (for reasons such as compactness). As a result, the total (distributed) capacitance on a bit line in combination with the relatively large resistance presented by the small-sized transistor may lead to longer access times.

The present invention provides a mask ROM device with a comparatively higher speed of operation.

### BRIEF DESCRIPTION OF THE DRAWINGS

The present invention will be described with reference to the following accompanying drawings, which are described briefly below.

FIG. 1 is a circuit diagram illustrating the details of a prior mask ROM unit

FIG. 2 is a block diagram of a mask ROM unit according to several aspects of the present invention.

FIG. 3 is a circuit diagram illustrating the details of a memory cell used in a mask ROM unit in an embodiment of the present invention.

FIG. 4 is a block diagram illustrating the details of an example device incorporating several aspects of the present invention.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

According to an aspect of the present invention, a ROM unit contains a memory cell that provides a differential output representing the stored data bit. A sense amplifier receives the differential output to generate a logic value equal to the stored data bit. The use of differential sensing mitigates the effect of noise that may be present in the input path to the sense amplifier. As a result, the sense amplifier may be able to reliably determine the stored bit value at a lower value of differential voltage provided to it, thus improving speed of operation of the ROM unit.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

### 2. Prior Mask ROM Unit

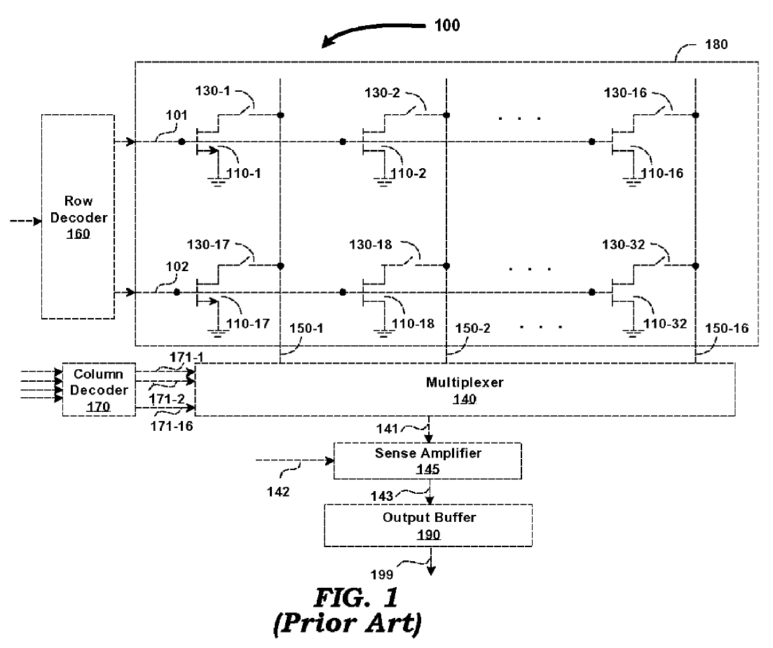

FIG. 1 is a circuit diagram illustrating the details of a prior mask ROM unit. Mask ROM unit 100 is shown containing row decoder 160, column decoder 170, memory array 180, multiplexer 140, sense amplifier 145, and output buffer 190. Merely for conciseness, memory array 180 is shown containing only 32 bit cells organized in the form of 2 rows, with each row containing 16 bit cells. The 32 bit cells are respectively implemented using 32 transistors 110-1 through 110-32. In the description below, the terms bit cell and transistor are used interchangeably.

Row decoder 160 receives 1-bit of a 5-bit address, and enables (sets to 1) one of word lines101 and 102 depending on the value of the 1-bit. Column decoder 170 receives the remaining 4 bits and enables one of the 16 bit-lines 171-1 through 171-16 each of which is applied to enable a corresponding circuit/path in multiplexer 140. As described below, the data stored in one of the 32 bit cells (corresponding to the value of the 5 bit address) is provided on path 199.

Each word line is shared by all the bit cells in a row. Thus, word line 101 is shared by (connected to the gate terminal of) transistors 110-1 through 110-16, and word line 102 is shared by transistors 110-17 through 110-32. Similarly, each of bit lines 150-1 through 150-16 is shared by all bit cells in the corresponding column. For example, bit line 150-1 is shared by transistors 110-1 and 110-17 since the corresponding drain terminals are connected to bit line 150-1 via respective switches 130-1 and 130-17.

Each bit cell is programmed to either a 0 or 1 depending on whether the drain terminal is connected (or not) to the corresponding bit line through corresponding one of switches 130-1 through 130-32.

In operation, broadly, all the bit lines 150-1 through 150-16 are first charged to a voltage substantially equal to a power supply voltage (Vdd, not shown) when all the gate terminals (word lines) are disabled. When a corresponding line (101 or 102) is enabled a transistor present in that row discharges the corresponding bit-line if the corresponding switch is closed (due to the connection of the source terminal to Vss/ground), and a logic 0 would be read from the bit-line. If the switch corresponding to the selected (by word line) transistor in the column is open, the bit line remains charged, and thus a logic 1 would be read from the column.

Thus, transistor 110-1 is programmed to generate a 1 since the corresponding switch 130-1 is open. Transistor 110-18 is programmed to generate a 0 since the corresponding switch 130-18 is closed. The stored bit is provided on the corresponding bit line when the corresponding word line is set to 1.

Multiplexer 140 is connected to bit-lines 150-1 through 150-16, and selects one of the bits depending on the enabled one of column select lines 171-1 through 171-16. Multiplexer 140 provides voltage on the selected bit-line on path 141 to sense amplifier 145.

Sense amplifier 145 senses a signal (corresponding to the selected bit-line) on path 141 in response to a sense-enable signal received on path 142 (which may be generated internally in mask ROM unit 100), and provides an amplified version of the sensed signal (corresponding to the selected bit-line) on path 143. Output buffer 190 receives the amplified signal on path 143, and provides a buffered output of the received signal on path 199.

In operation, to retrieve a bit, a 5-bit address is generated, with 1-bit being provided as input to row decoder 160, and the remaining 4 bits being provided to column decoder 170. Only one of the word/row lines (101 and 102) and one of the column select lines (171-1 through 171-16) is set to 1 (“enabled”) as described above.

The bits stored in the rows corresponding to the enabled word line are provided on the corresponding bit lines (due to the turning on of the corresponding transistors only). The column decoder 170 enables a corresponding circuit/path in multiplexer 140 which forwards the selected signal to sense amplifier 145. Sense amplifier 145 senses the received signal in response to a sense enable signal (path 142), and provides an amplified version (representing a logic 0 or 1) of the received signal to output buffer 190, which in turn forwards a buffered version of the received signal on path 199. Thus, the bit specified by the 5-bit address is received on path 199.

Mask ROM unit 100 described above, however, has some disadvantages. Typically, each of transistors 130-1 through 130-32 is implemented as a small area (small width/small length) transistor. When the number of rows is large, the transistor would have to discharge the effectively large capacitance presented by a bit line (150-1 through 150-16). Further, external noise may be present/coupled on the bit-lines. Consequently, sense amplifier 145 would need to wait for a (relatively) large voltage to build up on the corresponding bit line before the sensing operation, so that a reliable determination of the bit value may be made. This results in slower operating speeds.

The present invention overcomes this disadvantage by employing differential sensing to retrieve a bit value stored in a memory cell in a mask ROM, and is described in detail below.

### 3. Mask ROM Unit with Differential Sensing

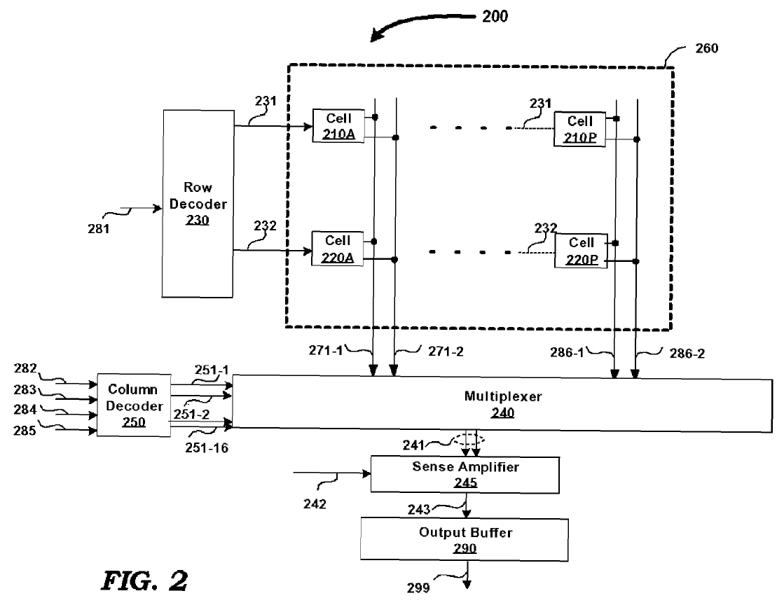

FIG. 2 is a block diagram illustrating the details of a mask ROM unit in an embodiment of the present invention. Mask ROM unit 200 is shown containing row decoder 230, memory array 260, multiplexer 240, sense amplifier 245, column decoder 250, and output buffer 290. Each component is described in detail below.

Row decoder 230 receives 1-bit (on path 281) of a 5-bit access address, and enables (sets to 1) one of word lines 231 and 232 depending on the value of the 1-bit. Column decoder 250 receives the remaining 4 bits (on paths 282-285 respectively), and enables a corresponding circuit/path in multiplexer 240. Row decoder 230 and column decoder 250 together constitute a decoder circuit.

Cells 210A-210P provide a differential voltage representing the value of the corresponding stored bit on corresponding differential bit-lines 271-1/271-2 through 286-1/286-2 in response to an enable signal received on word line 231. Similarly, cells 220A-220P provide a differential voltage representing the value of the corresponding stored bit also on corresponding differential bit-lines 271-1/271-2 through 286-1/286-2 in response to an enable signal received on word line 232.

Multiplexer 240 is connected to differential bit-lines 271-1/271-2 through 286-1/286-2, and selects one of the differential bit-lines depending on the enabled one of column select lines 251-1 through 251-16. Multiplexer 240 provides the differential voltage on the selected differential bit-line on (differential pair) path 241 to sense amplifier 245.

Sense amplifier 245 receives a differential signal on path 241, and in response to a sense enable signal 242 senses (measures) the differential voltage present on path 241 to provide an amplified voltage (representing the data bit stored in a corresponding memory cell) on path 243. Sense amplifier 245 may be implemented using techniques similar to those described in U.S. Pat. No. 7,072,236 entitled, “Semiconductor memory device with pre_sense circuits and a differential sense amplifier” issued to Matsuoka, and U.S. Pat. No. 7,054,213 entitled, “Method and circuit for determining sense amplifier sensitivity” issued to Laurent. Output buffer 290 receives the amplified signal on path 243, and provides a buffered output of the amplified signal on path 299.

Sense amplifier 245 in conjunction with multiplexer 240 may be referred to collectively as an access circuit, as they operate to enable retrieval (access) of the data bits stored in memory array 260.

The manner in which the data bit stored in memory cells 210A-210P and 220A-220P is retrieved and provided as an output on path 299 is similar to the description provided with respect to mask ROM unit 100 of FIG. 1 (except that each cell drives two bit lines to support the differential operation), and is not repeated here in the interest of conciseness.

It may be noted from FIG. 2 that the output of a cell is provided in a differential form to a sense amplifier on a corresponding differential bit line-pair. For example, cell 210A when enabled by row decoder 230 provides a differential voltage on differential bit-line pair 271-1/271-2 to sense amplifier 245 via multiplexer 240. Thus, it may be appreciated that any noise coupled (present) in the bit lines would appear as a common-mode signal to the sense amplifier and thus would be substantially rejected.

Therefore, sense amplifier 245 may make a determination of a stored bit value reliably even at lower (differential) voltages. Thus, a reliable determination of a stored data bit value may be made without having to wait for a longer time for the voltage on a bit-line (as in the case of mask ROM unit 100 of FIG. 1) to build up to a larger value. As a result, mask ROM unit 200 may operate at a higher speed in comparison with mask ROM unit 100 of FIG. 1.

The description is continued with the details of a memory cell contained in one embodiment of the present invention.

### 4. Memory Cell Providing Differential Outputs

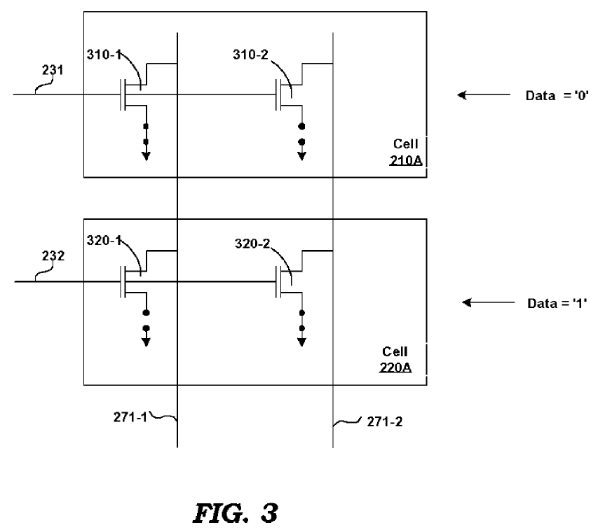

FIG. 3 is a circuit diagram illustrating the details of a memory cell according to an aspect of the present invention. The diagram is shown containing cell 210A and 220A, described above with respect to FIG. 2.

Cell 210A contains NMOS transistors (NMOS) 310-1 and 310-2, with the gate terminals of each of NMOS 310-1 and 310-2 being connected to word line 231. The drain terminal of NMOS 310-1 is connected to bit-line 271-1 and the drain terminal of NMOS 310-2 is connected to bit-line 271-2. The source terminal of NMOS 310-1 is shown as being connected to a ground terminal (in one form of configuration), while the source terminal of NMOS 310-2 is shown as being unconnected (floating) (another form of configuration).

Thus, when word line 231 is active (e.g., a logic 1) NMOS 310-1 is ON, and bit-line 271-1 starts to discharge towards ground potential (nominally zero volts, and representing a logic 0). NMOS 310-2 is always OFF as the source terminal is floating, and consequently bit-line 271-2 is at a precharged level (nominally the power supply voltage, and representing a logic 1). It may be noted here, that differential bit-line pair 271-1/271-2 are precharged to the power supply voltage before very read (access) cycle, as is well known in the relevant arts.

Consequently, the differential voltage across differential bit-line pair 271-1/271-2 will start transitioning from (nominally) zero volts to a voltage equal to a negative magnitude of the power supply voltage, considering bit-line 271-1 to be a positive (+) terminal and bit-line 271-2 to be a negative (−) terminal. This negative voltage on differential bit-line pair 271-1/271-2 represents the data bit logic 0 stored in cell 210A.

Cell 220A contains NMOS transistors (NMOS) 320-1 and 320-2, with the gate terminals of each of NMOS 320-1 and 320-2 being connected to word line 232. The drain terminal of NMOS 320-1 is connected to bit-line 271-1 and the drain terminal of NMOS 320-2 is connected to bit-line 271-2. The source terminal of NMOS 320-1 is shown as being unconnected, while the source terminal of NMOS 320-2 is shown as being connected to a ground terminal.

Thus, when word line 232 is active (e.g., a logic 1) NMOS 320-2 is ON, and bit-line 271-2 starts to discharge towards ground potential (nominally zero volts). NMOS 320-1 is always OFF as the source terminal is floating, and consequently bit-line 271-1 is at the precharged level.

Consequently, the differential voltage across differential bit-line pair 271-1/271-2 will start transitioning from (nominally) zero volts to a voltage equal to a positive magnitude of the power supply voltage. This positive voltage on differential bit-line pair 271-1/271-2 represents the data bit logic 1 stored in cell 220A.

As noted earlier, sense amplifier 245 senses the differential voltage across differential bit-line 271-1/271-2, and can make a reliable determination of the corresponding data bit.

It may be noted that the source terminals of NMOS transistors 310-1/310-2, and 320-1/320-2 are configured (connected) such that when a memory cell (210A or 220A) is enabled (accessed) the logic value driven on bit-line 271-1 is complementary to that driven on bit-line 271-2. Although NMOS transistors have been shown as being used to implement memory cells in memory array 260 of FIG. 2, other components which can be configured as electronic switches may also be used.

While the various aspects of the present invention have been described with respect to a mask ROM, at least some aspects also apply to other types of ROM such as Erasable Programmable ROM (EPROM), Electrically Erasable Programmable ROM (EEPROM) etc.

A mask ROM unit designed according to aspects of the present invention may be incorporated in many devices/components. The description is continued with an example device as described next.

### 5. Device

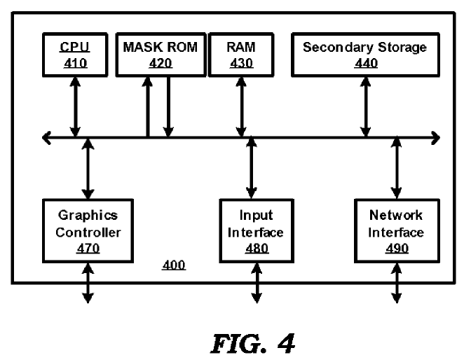

FIG. 4 is a block diagram illustrating the details of an example device in accordance with an aspect of the present invention. Device 400 is shown containing CPU 410, mask ROM 420, RAM 430, secondary storage 440, graphics controller 470, input interface 480 and network interface 490. Each component is described in further detail below.

CPU 410 executes various instructions retrieved from RAM 430. RAM 430 provides various data and instructions for execution by CPU 410. The data and instruction may be provided from secondary storage 440. CPU 410, RAM 430 and secondary storage 440 may be implemented in a known way.

Graphics controller 470 provides display signals which are eventually displayed on a display unit (not shown). Input interface 480 represents devices such as key-boards which are used by a user to provide input interactively. Network interface 490 is used to send/receive various data packets.

Mask ROM 420 may be implemented according to various aspects of the present invention described above, and may store any configuration data and/or instructions, which are used during operation by CPU 410. CPU 410 may provide the access addresses to retrieve the data elements of interest.

### 6. Conclusion

While various embodiments of the present invention have been described above, it should be understood that they have been presented by way of example only, and not limitation. Thus, the breadth and scope of the present invention should not be limited by any of the above-described embodiments, but should be defined only in accordance with the following claims and their equivalents.

What is claimed is:

1. A read only memory (ROM) unit comprising:
a memory array containing a plurality of memory cells, with each memory cell storing a data value, said memory array being designed to provide said data value in the form of a differential signal;
a decoder circuit generating signals causing said memory array to provide said differential signal representing said data value stored in a first memory cell, wherein said first memory cell is specified by at least a portion of an access address; and
an access circuit receiving said differential signal and generating said data value in said first memory cell as an output of said ROM unit.

2. The ROM unit of claim 1, wherein said first memory cell comprises a first component and a second component, said first component being coupled to a first bit-line to provide a first output voltage, and said second component being coupled to a second bit-line to provide a second output voltage, said first output voltage and said second output voltage together providing said data value in said differential form.

3. The ROM unit of claim 2, wherein said first output voltage and said second output voltage respectively represent a first state and a second state, wherein said first state is complementary to said second state.

4. The ROM unit of claim 3, wherein said first component comprises a first transistor having a terminal configured to represent said first state and said second component comprises a second transistor having a terminal configured to represent said second state.

5. The ROM unit of claim 4, wherein said memory array comprises a word line coupled to a first row of transistors, wherein said word line is enabled by an output of said decoder circuit, said first transistor and said second transistor being contained in said first row of transistors, another terminal of said first transistor being coupled to said first bit line and said another terminal of said second transistor being coupled to said second bit line, wherein said access circuit comprises:
a sense amplifier coupled to said first bit-line and said second bit-line to receive said differential signal and generates said data value.

6. The ROM unit of claim 5, wherein said terminal comprises a source terminal and said another terminal comprises a drain terminal.

7. The ROM unit of claim 6, wherein said data value comprises a bit.

8. A ROM unit comprising:
memory means for storing a plurality of data values in the form of an array;
means for receiving an address specifying a first data value contained in said plurality of data values;
means for providing said first data value as a signal in differential form from said array;
means for sensing said signal in differential form to determine said first data value; and
means for outputting said first data value as being stored at said address.

9. The ROM unit of claim 8, wherein each of said plurality of data values represent a logic 1 or a logic 0, said memory means for storing contains a first transistor in a first configuration and a second transistor in a second configuration to represent said logic 1, and said first transistor to said second configuration and said second transistor to said first configuration to represent said logic 0.

10. The ROM unit of claim 9, wherein said means for providing provides said signal on a first bit line and a second bit line, wherein said first transistor is connected to drive said first bit line and said second transistor is connected to drive said second bit line.

11. The ROM unit of claim 10, wherein each of said first transistor and said second transistor comprises a NMOS transistor, wherein said first configuration comprises a connection of a source terminal to ground and said second configuration comprises leaving said source terminal floating.

12. A method implemented in a ROM unit, said method comprising:
storing a plurality of data values in a memory array;
receiving an address specifying a first data value contained in said plurality of data values;
providing said first data value as a signal in differential form from said memory array;
sensing said signal in differential form to determine said first data value; and
outputting said first data value as being stored at said address.

13. The method of claim 12, wherein each of said plurality of data values represent a logic 1 or a logic 0, said storing comprises configuring a first transistor in a first configuration and a second transistor in a second configuration to represent said logic 1, and configuring said first transistor to said second configuration and said second transistor to said first configuration to represent said logic 0.

14. The method of claim 13, wherein said providing provides said signal on a first bit line and a second bit line, wherein said first transistor is connected to drive said first bit line and said second transistor is connected to drive said second bit line.

15. The method of claim 14, wherein each of said first transistor and said second transistor comprises a NMOS transistor, wherein said first configuration comprises a connection of a source terminal to ground and said second configuration comprises leaving said source terminal floating.

16. A device comprising:
a processor processing a digital data; and
a read-only memory (ROM) unit providing said digital data, said ROM unit comprising:
a memory array containing a plurality of memory cells, with each memory cell storing a data value, said memory array being designed to provide said data value in the form of a differential signal;
a decoder circuit generating signals causing said memory array to provide said differential signal representing said data value stored in a first memory cell, wherein said first memory cell is specified by at least a portion of an access address; and
an access circuit receiving said differential signal and generating said data value in said first memory cell as an output of said ROM unit.

17. The device of claim 16, wherein said first memory cell comprises a first component and a second component, said first component being coupled to a first bit-line to provide a first output voltage, and said second component being coupled to a second bit-line to provide a second output voltage, said first output voltage and said second output voltage together providing said data value in said differential form.

18. The device of claim 17, wherein said first output voltage and said second output voltage respectively represent a first state and a second state, wherein said first state is complementary to said second state.

19. The device of claim 18, wherein said first component comprises a first transistor having a terminal configured to represent said first state and said second component comprises a second transistor having a terminal configured to represent said second state.

20. The device of claim 19, wherein said memory array comprises a word line coupled to a first row of transistors, wherein said word line is enabled by an output of said decoder circuit, said first transistor and said second transistor being contained in said first row of transistors, another terminal of said first transistor being coupled to said first bit line and said another terminal of said second transistor being coupled to said second bit line, wherein said access circuit comprises:
a sense amplifier coupled to said first bit-line and said second bit-line to receive said differential signal and generates said data value.
